(19) United States
(12) Patent Application Publication
(10) Pub. No.: US 2011/0227055 A1
(43) Pub. Date: Sep. 22, 2011

(54) PROCESS FOR THE PREPARATION OF ORGANIC ELECTRONIC DEVICES

(75) Inventors: Miguel Carrasco-Orozco, Winchester (GB); Paul Craig Brookes, Southampton (GB); Katie Patterson, Portsmouth (GB); Frank Egon Meyer, Hampshire (GB); Mark James, Romsey (GB); Toby Cull, Newbury (GB); David Christoph Mueller, Frankfurt am Main (DE)

(73) Assignee: MERCK PATENT GESELLSCHAFT MIT BESCHRANKTER HAFTUNG, Darmstadt (DE)

(21) Appl. No.: 13/130,800

(22) PCT Filed: Nov. 9, 2009
(86) PCT No.: PCT/EP2009/007985

§ 371 Date: May 24, 2011

(30) Foreign Application Priority Data
Nov. 24, 2008 (GB) 0821393.6

(51) Int. Cl. H01L 51/10; H01L 21/336; B05D 5/12; B05D 5/06

(52) U.S. Cl. 257/40; 438/158; 427/525; 257/E51.007; 257/E21.411

(57) ABSTRACT

The invention relates to the use of a closed field unbalanced magnetron sputter ion plating process in the preparation of organic electronic devices or components thereof, and to organic electronic devices, or components thereof, obtainable by such a process.

### FIELD OF THE INVENTION

The invention relates to the use of a closed field unbalanced magnetron sputter ion plating process in the preparation of organic electronic devices or components thereof, and to organic electronic devices or components thereof obtainable by such a process.

### BACKGROUND AND PRIOR ART

Organic field effect transistors (OFETs) are used in display devices and logic capable circuits. A conventional OFET typically comprises source, drain and gate electrodes, a layer of an organic semiconductor (OSC) material, and a gate insulator layer comprising an organic dielectric material.

For the preparation of a bottom gate (BG) OFET device, usually the source and/or drain electrode layer, consisting of a metal or metal oxide, is deposited onto the dielectric layer by a plasma assisted sputtering process, followed by lithographic etching to remove unwanted areas.

However, it is known that sputtering metals on top of a functional organic material has a detrimental effect on its properties and functionality. For instance, in the field of OLEDs, the sputtering of a metal has been reported to imply a reduction of the performance which needs to be corrected by introducing buffer layers (see J. Meyer, T. Winkler, S. Hamwi et al, Adv. Mater. 2008, 20, 3839). In case of OFET devices, it was observed that the electrode sputtering process can cause significant damage on the exposed parts of the surface of the dielectric layer. As a result, the device performance is deteriorating.

WO 2008/131836 A1 discloses a process for preparing an OFET device, wherein a sacrificial layer is applied on top of the dielectric layer to protect it against damage caused by sputtering or plasma treatment during deposition of the metal electrodes. However, this requires additional process steps.

Especially in case of dielectric layers having a low dielectric constant or permittivity (“low k”) as used in organic electronic devices, the sputtering process affects the chemical and physical properties of the layer at the dielectric/semiconductor interface. This damage can be attributed to the effect of plasma to the organic materials properties. Both carbon depletion and surface densification has been observed on the top surface of damaged low k materials while the bulk remained largely unaffected.

Bao et al. J. Vac. Sci. Technol. B, Vol. 26, No. 1, January/February 2008, disclose a mechanistic study of plasma damage to low k dielectric materials, and report that this was found to be a complicated phenomenon involving both chemical and physical effects, depending on chemical reactivity and the energy and mass of the plasma species. The investigated low k materials were organosiloxanes based on methylsilsequioxane (MSQ) with Si—O—Si backbone bonds and incorporating methyl groups and porosity to reduce the dielectric constant. It is reported that the dielectric constant of the low k materials can increase up to 20% due to plasma damage, which was attributed to the removal of the methyl group, making the low k surface hydrophilic. It is also reported that annealing was generally effective in mitigating moisture uptake to restore the k value, but the recovery was less complete for higher energy plasmas.

It is an aim of the present invention to provide an improved process for preparing optical, electrooptical and electronic devices like OFETs, wherein during deposition of a metal or conductive layer (for example an electrode) onto an organic layer (for example the gate dielectric) the damage to the organic layer is reduced in comparison to the methods known in prior art, without the need of applying additional process steps. The process should be time-, cost- and material-effective and suitable for large scale manufacture. Another aim of the invention is to provide improved processes for the deposition of metals or other conducting materials onto organic materials. Another aim of the invention is to provide improved optical, electrooptical and electronic devices, especially OFETs, obtained by such a process. Other aims of the present invention are immediately evident to the expert from the following detailed description.

It was found that these aims can be achieved by providing a process as claimed in the present invention.

In particular, the inventors of this invention have found that, by using a specific magnetron sputter ion plating (MSIP) process, also known in the literature as Closed Field Unbalanced Magnetron Sputter Ion Plating (CFUBMSIP), it is possible to sputter metals, metal oxides or other conducting layers on top of an organic material with minimal or no damage to its electronic properties during the manufacture of an organic electronic device. It was also surprisingly found that in particular in case of low k dielectric materials the damage can be significantly reduced.

E. Lugscheider, S. Bärwulf, C. Barimani, M. Riester, H. Hilgers, Mat. Res. Soc. Symp. Proc. Vol. 544, 1999, p. 191-196, report the use of an MSIP process for depositing thin layers of Ti or Ti—N on the surface of a thermo-plastic polymer product (e.g. a storage disk) to improve its surface properties such as wear resistance, corrosion resistance and electrical conductivity (to avoid electrostatic discharges). However, CFUBMSIP or its use for preparing functional layers in electronic devices are not disclosed.

U.S. Pat. No. 5,556,519 and U.S. Pat. No. 6,423,419 disclose a CFUBMSIP process and apparatus to provide metal, metal oxide or metal sulphide coatings onto metal or metal carbide articles like e.g. cutting tools, for the purpose of surface hardening. U.S. Pat. No. 6,726,993 and V. Rigato, D. Teer et al., Surface and Coatings Technology 116-119 (1999), 580-584 disclose a CFUBMSIP process for providing a carbon coating onto articles or substrates like silicon single crystal wafers, for the purpose of improving their hardness and wear resistance. WO2005/110698 A1 discloses a CFUBMSIP process for providing a metal nitride coating onto a moulding tool for improving its non-stick characteristics, to prevent undesired adhesion and sticking of the formed article, e.g. a moulded plastic, to the moulding tool.

However, so far it has not been disclosed or suggested to use the CFUBMSIP technique for sputtering metal or metal oxide layers directly onto organic substrates, or to use this techniques for applying a functional layer, like for example an electrode, in an organic electronic or electrooptical device.

### SUMMARY OF THE INVENTION

The invention relates to the use of closed field unbalanced magnetron sputter ion plating (CFUBMSIP) for depositing a conducting material, for example as a layer, onto an organic material.

The invention further relates to a process of depositing a conducting material, for example as layer, onto an organic material by CFUMBSIP.

The invention further relates to a process or use as described above and below for manufacturing an optical, electrooptical or organic electronic device or a component thereof, including the step of depositing a layer of a conducting material onto a layer of an organic material by CFUBMSIP.

Preferably the process as described above and below is used for providing a functional device layer of a conducting material, very preferably an electrode, preferably onto another functional device layer comprising an organic material, like for example a dielectric layer.

The invention further relates to a process or use as described above and below, wherein the layer of organic material is a dielectric layer, preferably a gate insulator layer, in an optical, electrooptical or organic electronic device.

The invention further relates to a process or use as described above and below, wherein the layer of conducting material is an electrode layer, preferably a source, drain or gate electrode, in an optical, electrooptical or organic electronic device.

The invention further relates to an optical, electrooptical or organic electronic device, or a component thereof, obtainable or obtained by a process or use as described above and below.

Said optical, electrooptical or organic electronic device, or component thereof, is preferably selected from the group consisting of electrooptical displays, liquid crystal displays (LCDs), optical information storage devices, electronic devices, organic semiconductors, organic field effect transistors (OFET), integrated circuits (IC), organic thin film transistors (OTFT), Radio Frequency Identification (RFID) tags, organic light emitting diodes (OLED), organic light emitting transistors (OLET), electroluminescent displays, organic photovoltaic (OPV) devices, organic solar cells (O-SC), organic laser diodes (O-laser), organic integrated circuits (O-IC), lighting devices, flat panel displays (FPD), sensor devices, electrode materials, photoconductors, photodetectors, electrophotographic recording devices, capacitors, charge injection layers, Schottky diodes, planarising layers, antistatic films, conducting substrates, conducting patterns.

### BRIEF DESCRIPTION OF THE DRAWINGS

FIGS. 1 and 2 schematically depict an CFUBMSIP apparatus as used in the process of the present invention.

FIG. 3 shows the ion current against substrate bias voltage for different system configurations of the CFUBMSIP process.

FIG. 4 shows the ion current against bias voltage for two different levels of current applied to the magnetrons in the CFUBMSIP process.

FIG. 5 schematically and exemplarily illustrates a BG FET structure.

FIG. 6 shows the transistor characteristic of a reference BG FET device obtained according to Comparative Example 1.

FIGS. 7 and 8 show the transistor characteristic of FETs obtained according to Comparative Example 2.

FIG. 9 shows the transistor characteristic of a FET obtained according to Comparative Example 3.

FIGS. 10 and 11 show the transistor characteristic of FETs obtained according to Example 1 using a CFUBMSIP process.

FIG. 12 shows the transistor characteristic of a FET obtained according to Example 2 using a CFUBMSIP process.

### TERMS AND DEFINITIONS

The term “thin film” means a film having a thickness in the range from several nm to several μm, in case of functional layers of electronic or electrooptical devices usually in the range from 1 nm to 2 μm, preferably from 10 nm to 1 μm.

The terms “film” and “layer” include rigid or flexible, self-supporting or free-standing films with mechanical stability, as well as coatings or layers on a supporting substrate or between two substrates.

The term “conducting material” means an electrically conducting material, preferably having a surface resistivity <10Ω (also given as “Ω/square”), very preferably <1Ω, very preferably <0.1Ω (measured by standard 4 probes technique). This includes for example metals, metal oxides, metal sulphides, metal nitrides, carbon, silicon oxide, silicon nitride, or mixtures or combinations of one or more of the aforementioned (like for example metal-nitride-oxide-silicon, “MNOS”).

“Permittivity” unless stated otherwise means the relative static permittivity (also known as “dielectric constant”), abbreviated by ε_{γ} or k, defined as

ε_{γ}=ε_{S}/ε₀

wherein ε_{S} is the static permittivity of the material, and ε₀ is the electric constant, with the linear relative permittivity of vacuum being 1. The relative static permittivity can be measured for static electric fields as follows: first the capacitance of a test capacitor C₀ is measured with vacuum between its plates. Then, using the same capacitor and distance between its plates the capacitance C_{χ} with a dielectric between the plates is measured. The relative permittivity can be then calculated as

ε_{γ}=C_{χ}/C₀.

For time-variant electromagnetic fields, this quantity becomes frequency dependent and in general is called relative permittivity.

Unless stated otherwise, the permittivity values given in this application refer to the low frequency permittivity, which is measured between 50 to 10,000 Hz, by the ASTM D150 test method. Permittivity values of known polymers can also be found, for example, in the Handbook of Electrical and Electronic Insulating Materials (The Institute of Electrical and Electronic Engineers Inc., New York, 1995). It is generally preferred that the permittivity of the dielectric material according to the present invention has little dependence of frequency.

The term “organic material” as used above and below includes organic materials like for example hydrocarbons and their derivatives, which may also include heteroatoms like for example Se, Te, P, Si, B, As, N, O or S, but does also include hybrids of organic and inorganic materials, like for example micro- or nanoparticles essentially consisting of inorganic materials which are e.g. dispersed or otherwise embedded into a matrix of an organic material.

The term “organic electronic device” means an electronic device that contains at least one functional layer comprising an organic material, wherein said functional layer can be for example the semiconductor layer or the dielectric (insulator) layer.

The term “dielectric” also includes the meaning “insulator”, wherein “insulator” means an electrical insulator.

### DETAILED DESCRIPTION OF THE INVENTION

This invention provides a novel usage of closed field unbalanced magnetron sputter ion plating (CFUBMSIP). In this invention CFUBMSIP is used to sputter metals and other conducting materials on top of organic materials, for example when providing electrode layers onto organic layers, films or substrates, with minimal or no damage to the electronic properties of the organic layer.

Metal deposition by sputtering is generally preferred in the electronic industry over thermal metal deposition methods. Amongst the reasons is the better thickness uniformity, and the fact that the sputtered metal composition is identical to the target, except in case of reactive sputtering where it is deliberately modified to a specific stoichiometry.

One particular problem to be solved by this invention is the identification of a modified way of sputtering metals and conducting materials, like for example Ag or ITO, on top of an organic material without damaging it. This would remove one of the biggest hurdles in the replacement of Si technology in the LC-display manufacturing, allowing organic semiconductors and matching (low k) organic dielectrics to be used.

The inventors of the present invention have found that this problem can be solved by using a CFUBMSIP process.

Suitable methods and apparatus for applying CFUBMSIP are described for example in U.S. Pat. No. 5,556,519, U.S. Pat. No. 6,423,419, U.S. Pat. No. 6,726,993, WO 2005/110698 and V. Rigato, D. Teer et al., Surface and Coatings Technology 116-119 (1999), 580-584, with the entire disclosure of each of these documents being incorporated into this application by way of reference. In these documents the CFUBMSIP technique is disclosed for providing metal, metal oxide, metal sulphide, metal nitride or carbon coatings onto articles like cutting tools, moulding tools or silicon single crystal wafers, e.g. for the purpose of hardening, improving wear-resistance, or reducing the adhesion to moulded plastic articles. However, so far it was not disclosed or suggested to use CFUBMSIP for sputtering metals or metal oxides onto organic substrates, or for applications related to the field of organic electronic devices.

Description of the MSIP or CFUBMSIP Technique

The CFUBMSIP technique has been developed by Teer Coatings Ltd. (UK). It utilizes unbalanced magnetrons, which are surrounding the substrate to be sputtered in such an arrangement that neighbouring magnetrons are of opposite magnetic polarity. Thereby the deposition zone in which the substrate is located is surrounded by linking magnetic field lines, creating a close field magnetic system. As a consequence the plasma region is trapped, the ion current density is increased, and losses of ionising electrons are prevented, resulting in a significant plasma enhancement.

In the following the CFUBMSIP technique is described more in detail. A further description can be found in U.S. Pat. No. 5,556,519, U.S. Pat. No. 6,423,419, U.S. Pat. No. 6,726,993 and WO 2005/110698, with the entire disclosure of these documents being incorporated into this application by way of reference.

“Unbalanced magnetron” means that the magnetron has inner and outer magnets and the field strength of the outer magnets is much higher than the field strength of the inner magnets. The “extra” field lines leaving the outer magnets trap electrons escaping from the magnetron discharge and prevent them from drifting to the various earthed parts of the chamber. These electrons cause ionization in the vicinity of the electrically biased substrate and the ions so formed are attracted to the substrate by the substrate bias, and the substrates receive a higher ion current than in a situation where the magnetrons are balanced.

According to the CFUBMSIP technique there is provided a magnetron sputter ion plating system comprising electric field means for generating an electric field directed towards an electrically biased, cathode, substrate to be coated so as to attract ions to the substrate, and magnetic field means, the magnetic field means comprising at least two magnetrons each having an inner pole and an outer ring pole of opposite polarity, the magnetrons being so arranged that the outer ring pole of one magnetron and the outer ring pole of the other, or another, magnetron are of opposite polarities and are near enough to each other so that magnetic field lines extend between the outer ring poles of the magnetrons linking them so as to prevent the escape of electrons from the system between them so that these electrons are not lost to the system and are available to increase the ionization at the electrically biased substrate.

The magnetic field means generates a plasma holding field by direct magnetic linkage between the outer poles of adjacent magnetrons. The substrate is inside said plasma holding field.

The system further comprises a holding means for supporting the substrate to be coated, wherein in use the substrate is provided at said holding means and is electrically biased by said electric field to be a cathode so as to attract ions to the substrate.

The system may further comprise an earthed coating chamber comprising an anode of the apparatus.

Magnetrons having an inner pole and an outer ring pole are well known. The inner pole can be a single magnet, or a line or group of magnets. The outer “ring” pole can be formed from a single magnet or several separate magnets side by side. The “ring” need not be cylindrical or circular, but could be of square or rectangular shape, or indeed any suitable figure.

The linking of the two magnetrons by magnetic flux traps electrons in the system and increases the amount of ionization which occurs. This provides practical magnetron sputter ion plating systems that give significantly increased ionization using either balanced magnetrons or unbalanced magnetrons with outer magnets of moderate field strength.

Preferably the outer, ring, poles are angularly spaced relative to the position of the substrate to be coated so that they subtend a substantial angle at that substrate.

The system may comprise a plurality of magnetrons the adjacent outer poles, or end regions, of which are of opposite polarities. The magnetrons are preferably arranged around the substrate and the substrate may have a generally central position between the magnetrons. Preferably the magnetrons are equally-angularly spaced in a polygon or ring around the substrate.

The electric field may be provided extending substantially radially between the substrate and the magnetrons the substrate being at a negative electrical potential. The negative potential of the substrate may vary from zero up to substantially higher values, like for example 1000V.

The magnetron poles may comprise a target of source material from which ions are produced.

Preferably there is an even number of magnetrons.

The system may further comprise a pumping port to control the pressure of an ionising gas, such as argon, in the system.

In another embodiment the CFUBMSIP technique comprises a method of magnetron sputter ion plating a substrate to be coated comprising providing a first magnetron having an inner ring pole and an outer ring pole of opposite polarity, and a second magnetron having an inner and outer ring pole of opposite polarity, with the outer ring pole of the first magnetron being of opposite polarity to that of the second magnetron; electrically biasing a substrate to be coated so as to make it a cathode to attract positive ions; and reducing the leakage of electrons from between the magnetron by arranging for magnetic flux to extend between their outer ring poles, thereby trapping electrons which could otherwise escape between the magnetrons and increasing the coating ion density at the substrate to be coated. In this way the ion density at the electrically biased substrate is significantly increased

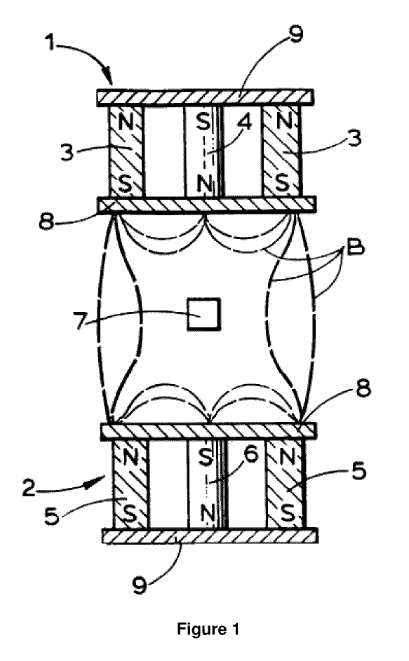

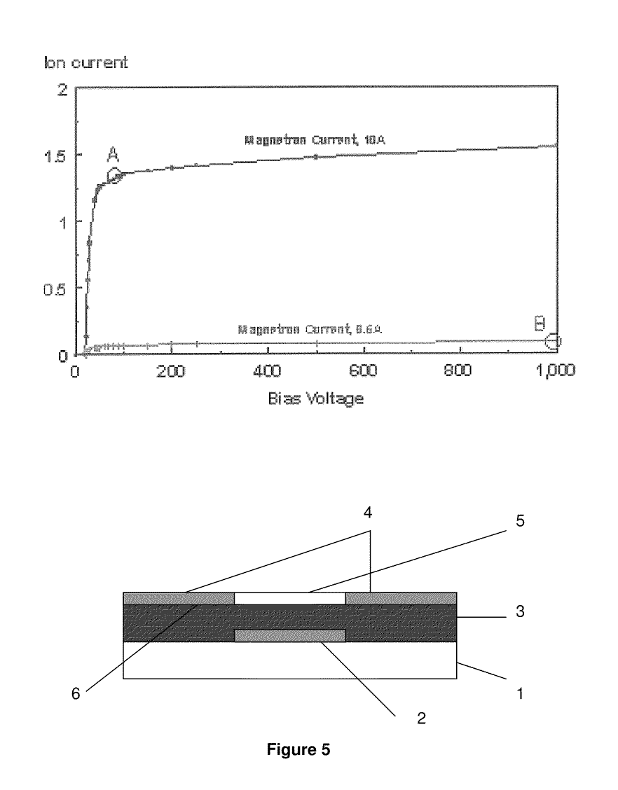

The design of a suitable CFUBMSIP apparatus is disclosed for example in U.S. Pat. No. 5,556,519. The closed field system includes any magnetron deposition system containing more than one magnetron where the linking of magnetic field lines from neighbouring magnetrons causes plasma enhancement. For example FIG. 1 of U.S. Pat. No. 5,556,519 shows a twin magnetron system with two magnetrons facing each other and having opposing magnetic polarity. FIG. 5 of U.S. Pat. No. 5,556,519 shows a four magnetron system, where the magnetrons are arranged such that the magnetic field forms a continuous ring and a closed system. FIG. 7 of U.S. Pat. No. 5,556,519 shows a six magnetron system assembly with six magnetron pole assemblies, wherein next-neighbour outer pole assemblies have opposite polarity.

A further modification is for example depicted in FIG. 3 of U.S. Pat. No. 5,556,519, showing a three magnetron system with three magnetron pole assemblies equi-angularly spaced with the substrate at the center of the triangle. A pumping port (not shown) can also be provided between the two adjacent poles of similar polarity of this assembly. Magnetic field lines extend from the adjacent ends of the magnetrons, and prevent the escape of electrons through the gaps between the magnetrons. Thus electrons cannot escape to ground parts of the system, except in the region of the pumping port.

FIG. 1 of this application exemplarily and schematically depicts a twin magnetron system suitable for the process of this invention, as also shown in FIG. 1 of U.S. Pat. No. 5,556,519. It includes two magnetrons (1) and (2), each of which comprises an outer ring magnet (3) and (5), and a central core magnet (4) and (6), respectively. An electrically biased substrate (7) to be coated is placed in the centre of the magnetron system. In the exemplary embodiment as shown in FIG. 1, the outer magnet (3) of magnetron (1) is of “south” polarity and the inner core magnet (4) is of “north” polarity in the region facing the substrate (7). The magnets (5) and (6) of magnetron (2) have reverse polarity, respectively. As a result the magnetic field lines of the magnetic field B that is created by the magnetrons (1) and (2) form a continuous barrier, thereby trapping electrons which diffuse from the magnetron plasmas. The magnetron poles (1) and (2) have target shrouds (8) of source material covering their exposed faces, and a soft iron backing plate (9) to complete their internal magnetic circuits.

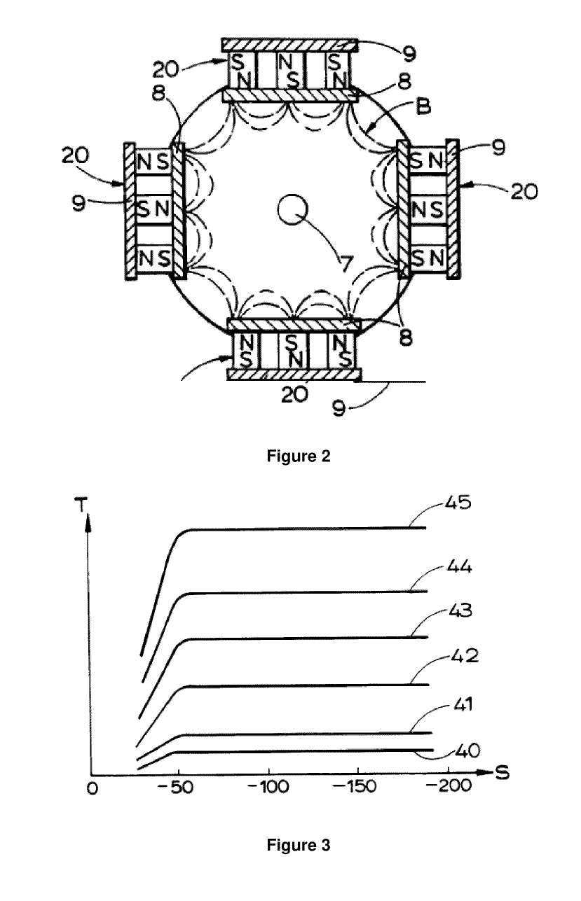

FIG. 2 of this application exemplarily and schematically depicts a four magnetron system suitable for the process of this invention, as also shown in FIG. 5 of U.S. Pat. No. 5,556,519. Therein, four magnetrons are provided equi-angularly spaced in a ring, and the substrate (7) is placed in the center of the ring. Each individual magnetron is similar to that described in FIG. 1. A pumping port (not shown) can also be provided out of the plane of the four magnetrons. For example the system can have the overall cylindrical shape of a dustbin and the pumping port is then provided at the base of the dustbin, with the magnetrons, and substrate, being located above the base. The magnetic field B forms a continuous ring surrounding the substrate and traps electrons in the ring. Since an even number of magnetron pole assemblies is provided the flux ring can be complete.

In use an inert gas such as argon is provided in the chamber of the system and electrons are accelerated in the chamber by a potential difference applied to the magnetron targets (8) to ionize the gas, producing more electrons and argon ions. The argon ions present in the chamber bombard the targets (8) of source material and produce a coating flux of source material. The argon ions also bombard the substrate. The magnetic field lines B serve to form a continuous barrier to the electrons diffusing from the magnetron discharges and ensure that these electrons are not lost to the system without performing their useful function of enhancing the glow discharge associated with the negatively electrically biased substrates, increasing the ion current to the substrate

Generally magnetron systems having an even number of magnetron pole assemblies, like two, four, six or eight, are especially preferred. Further preferred are magnetron pole assemblies wherein next-neighbour outer pole assemblies have opposite polarity (N/S), as shown for example in FIGS. 3, 5 and 7 of U.S. Pat. No. 5,556,519 and in FIG. 2 of this application.

FIG. 3 schematically shows the ion current (axis T) against substrate bias voltage (axis S, in Volts) for different magnetron system configurations, as also depicted in FIG. 9 of U.S. Pat. No. 5,556,519. Therein lines 40 and 41 represent three pole assemblies, all of the same polarity, lines 42 and 43 represent three pole assemblies with mixed or alternating polarity, and lines 44 and 45 represent four pole assemblies with mixed or alternating polarity. The assemblies of lines 40-44 use ferrite magnets, the assembly of line 45 uses an NdFeB magnet. The assembly of lines 40 is balanced, the assembly of lines 41-45 are unbalanced.

It can be seen that in direct comparison the ion current level is higher for an unbalanced assembly than for a balanced assembly, and higher for an assembly with alternating polarity than for an assembly where all poles have the same polarity. It can be also seen that the ionization enhancement effect of mixed or alternating polarity magnetrons is already effective when using relatively weak magnets like for example ferrites. The ionization enhancement effect is even stronger when using stronger magnetic materials such as NeFeB.

It can also be seen that the maximum ion current is already reached at a low bias voltage of ca. 50V. It is therefore possible to carry out deposition using a high density of low energy bombarding ions, resulting in very dense, non columnar coating structures with low internal stresses. In addition, using a low bias voltage during deposition enables the deposition of coatings with dense structures at low temperatures.

FIG. 4 shows the ion current (Y-axis) against bias voltage (X-axis, in Volts) for two different levels of current applied to the magnetrons. It can be seen that, if the magnetron current is increased, there is also a corresponding increase in ion bombardment, hence the ratio of ions to neutrals within the system is kept approximately constant. This ensures that the quality of the coatings produced by the system is independent of the deposition rate.

Preferably, prior to the deposition process an ion cleaning step is carried out in the CFUBMSIP apparatus, with the magnetrons being switched on at low power. The use of magnetrons at this stage allows a plasma to strike to the substrates at low Argon pressure preferably around 1×10⁻³ Torr, very preferably from 5×10⁻⁴ to 5×10⁻³ Torr. This is more effective than a high pressure plasma. Ion cleaning is carried out at point B on the graph of FIG. 4 with deposition at point A. The ion current at point B is approximately 100 times greater than in a conventional system without the closed field arrangement. As a consequence, the efficiency of ion cleaning is significantly increased, resulting in coatings with very high levels of adhesion.

The CFUBMSIP apparatus and method as used in the process of this invention, and as disclosed for example in U.S. Pat. No. 5,556,519, is meant to cover any magnetron sputter deposition system containing more than one magnetron where the linking of magnetic field lines from neighbouring magnetrons causes plasma enhancement as described above. For example, the magnetrons can be round or rectangular, and can be oriented with their long axis vertical or horizontal. The linking magnetic field lines lead to an enhancement of the plasma.

Use of CFUBMSIP for Sputtering Onto an Organic Material

The CFUBMSIP process is especially suitable for providing functional conducting layers, like for example electrodes, in organic electronic devices like organic transistors (OTFTs or OFETs). For example, an OFET with significantly good performance can be obtained when the source and drain (S/D) electrodes are provided using a CFUBMSIP process, compared to using a conventional magnetron sputtering ion plating (MSIP), and even compared to using an MSIP process with reduced plasma power.

Hitherto it has not been reported or suggested to use the CFUBMSIP technique for applications in the field of organic electronics. The present invention therefore provides for a new use of this technique in the organic electronics field, thereby also providing new and unexpected advantages.

An important advantage when using the CFUBMSIP technique for organic electronic applications is that the plasma is confined around the magnetrons, and is therefore not in direct contact, but instead kept far away from the sample or substrate to be coated. As a consequence the organic material is not directly exposed to the strong plasma radiation as in conventional sputtering methods, or only subjected to a minimised exposure.

The advantage of the process according to the present invention over conventional sputtering methods is particularly evident when it is used to prepare a BG TFT structure.

FIG. 5 schematically and exemplarily illustrates a typical BG TFT structure, comprising a substrate (1), a gate electrode (2), an organic dielectric layer (3), source (S) and drain (D) electrodes (4), and an organic semiconductor layer (5). (6) indicates the critical interface between the dielectric (3) and the S/D electrodes (4). It can clearly be seen that during deposition of the source/drain (S/D) electrodes (4), the top surface of the organic dielectric (3) will be exposed to plasma radiation.

Typically a 30 to 40 nm thick layer of metal, like for example Ag, is deposited and patterned as S/D electrode.

Suitable and preferred conducting materials include, without limitation, metals, metal oxides, metal sulphides, metal nitrides, carbon, silicon oxide, silicon nitride, or mixtures or combinations of one or more of the aforementioned, like for example metal-nitride-oxide-silicon (“MNOS”), SiOₓ, SiNₓ or SiₓON_{y}.

Preferred metals include, without limitation, Au, Ag, Cu, Al, Ni, Co, Cu, Cr, Pt, Pd, Ca, W, In, Pb or their mixtures. Preferred metal oxides include, without limitation, ITO (indium tin oxide), AZO (aluminum zinc oxides) and GaInZnO.

Very preferred conducting materials are selected from the group consisting of Ag, Ni, Co, Al, Au, Pt, Cu, Ca, W, In, Pb, ITO, AZO.

The layer of the sputtered conducting material preferably has a thickness from 5 nm to 1 μm, more preferably from 10 μm to 1 μm, very preferably from 20 nm to 1 μm, even more preferably from 20 nm to 500 nm, most preferably from 30 nm to 100 nm.

Preferably the organic material is a dielectric organic material also known as electrically insulating material.

Furthermore, it was surprisingly found that the CFUBMSIP process is especially suitable and effective for applying a metal or other conducting layer onto a dielectric organic material with a low permittivity (also known as “low k” dielectric), preferably of 5.0 or less, more preferably of 4.0 or less. In case such a low k dielectric material is used as substrate in the CFUBMSIP process, the potential damage caused by the sputtering is even more significantly reduced, compared to a conventional sputtering process, than in case of a dielectric material with a high permittivity.

Preferably the organic material has a permittivity of 20.0 or less, more preferably of 10.0 or less, even more preferably of 5.0 or less, very preferably of 4.0 or less, most preferably 3.0 or less, and of 1.0 or more, more preferably 1.8 or more.

The low permittivity organic material preferably has a conductivity <10⁻⁶ Scm, to avoid leakage to the gate.

Preferably the organic material is an organic polymer or a crosslinked organic polymer.

Organic dielectric materials that are suitable and preferred for the process according to the present invention include, without limitation, organic polymers, preferably fluorinated or perfluorinated hydrocarbon polymers, BCB (benzocyclobutene) or BCB polymers, polyacrylates, and polycycloolefins, like fluorinated para-xylene, fluoropolyarylether, fluorinated polyimide, polystyrene, poly(α-methylstyrene), poly(α-vinylnaphthalene), poly(vinyltoluene), polyethylene, cis-polybutadiene, polypropylene, polyisoprene, poly(4-methyl-1-pentene), poly(4-methylstyrene), poly(chlorotrifluoroethylene), poly(2-methyl-1,3-butadiene), poly(p-xylylene), poly(α-α-α′-α′tetrafluoro-p-xylylene), poly[1,1-(2-methyl propane)bis(4-phenyl)carbonate], poly(cyclohexyl methacrylate), poly(chlorostyrene), poly(2,6-dimethyl-1,4-phenylene ether), polyisobutylene, poly(vinyl cyclohexane), poly(vinylcinnamate), poly(4-vinylbiphenyl), poly(1,3-butadiene), polyphenylene, and copolymers containing one or more monomer units of the aforementioned polymers.

Further preferred are copolymers, including regular, random or block copolymers like poly(ethylene/tetrafluoroethylene), poly(ethylene/chlorotrifluoro-ethylene), fluorinated ethylene/propylene copolymer, polystyrene-co-α-methylstyrene, ethylene/ethyl acrylate copolymer, poly(styrene/10% butadiene), poly(styrene/15% butadiene), poly(styrene/2,4 dimethylstyrene), or polymers from the commercially available Topas® series (Ticona).

Preferably the organic dielectric material has a permittivity from 1.0 to 5.0, very preferably from 1.8 to 4.0.

Such low k materials are disclosed for example in US 2007/0102696 A1 or U.S. Pat. No. 7,095,044. Especially suitable and preferred materials of this type include, without limitation, polypropylene, polyisobutylene, poly(4-methyl-1-pentene), polyisoprene, poly(vinyl cyclohexane), BCB polymers, polyacrylates, polycycloolefins, fluorinated hydrocarbon polymers, perfluorinated hydrocarbon polymers, and copolymers containing one or more monomer units of the aforementioned polymers.

Particularly suitable are polyacrylates or photosensitive resins like those from the PC® series (JSR Corp.), like for example PC411B, PC403 or PC409, polycycloolefins like those from the Avatrel® series (Promerus LLC), fluorinated hydrocarbon polymers or copolymers, in particular perfluorinated hydrocarbon polymers (highly soluble perfluoropolymers) like those from the commercially available Cytop® series (Asahi Glass), TeflonAF® series (DuPont) or Hyflon AD® series (from Solvay). Cytop polymers are described in “Modern Fluoroplastics”, edited by John Scheris, John Wiley&Sons Ltd., 1997, Chapter: “Perfluoropolymers obtained by cyclopolymerisation” by N. Sugiyama, pages 541ff. Teflon AF is described in “Modern Fluoroplastics”, edited by John Scheris, John Wiley&Sons Ltd., 1997, Chapter: “Teflon AF amorphous fluoropolymers” by P. R. Resnick, pages 397ff. Hyflon AD is described in “High Performance Perfluoropolymer Films and Membranes” V. Arcella et. al., Ann. N.Y. Acad. Sci. 984, pages 226-244 (2003).

For specific devices it may be preferable to use a dielectric material with a higher permittivity >3.0, preferably >10.0, very preferably >20.0. Suitable and preferred organic dielectric materials of this type include, without limitation, for example, polvinylalcohol, polyvinylphenol, polymethylmethacrylate, cyanoethylated polysaccharides such as cyanoethylpullulane, high permittivity fluoropolymers such as polyvinylidenefluoride, polyurethane polymers and poly(vinyl chloride/vinylacetate) polymers.

The organic material is most preferably selected from the group consisting of BCB polymers, polycycloolefins and polyacrylates.

The organic material may be a hybrid of organic and inorganic materials, like for example micro- or nanoparticles essentially consisting of inorganic materials, which are e.g. dispersed or otherwise embedded into a matrix of an organic material.

The process of this invention utilizing the CFUBMSIP technique can be successfully and advantageously used to produce organic electronic devices, in particular BG transistors like TFTS or OFETs, which have significantly improved properties compared to devices prepared by using standard sputtering techniques, or which would not even work at all when being prepared by using standard sputtering techniques.

Apart of BG transistors, the process of this invention can also be used to prepare other TFT architectures, like for example top gate (TG) transistors, or to prepare other organic electronic devices, like diodes, photodiodes, LEDs, OLEDs, organic photovoltaics, solar cells, memory devices, liquid crystal displays, sensors and complementary transistors and diode logics. Generally it can be applied to any process or in any device where a metal or conducting oxide, like or example an electrode layer, is sputtered on top of an organic functional material or layer.

The process of this invention can also be used in all kind of organic electronic devices where amorphous silicon (a-Si) or polycrystalline silicon (poly-Si) is replaced by organic semiconducting materials.

For example, the process of this invention is also suitable for the preparation of transparent electrodes (like ITO) onto organic substrates in LCD or OLED devices, especially in flexible flat panel displays where the glass substrates are replaced by flexible plastic substrates.

The deposited layer of the conducting material can also be patterned or structured using standard techniques that are known to the skilled person and are described in the literature, like e.g. photolithography techniques. Thereby it is possible for example to form patterned electrodes, such as source and drain electrodes in a transistor or OPV device.

Very preferably the organic electronic device is a TFT or OFET, very preferably a BG TFT or OFET. A preferred device is schematically and exemplarily illustrated in FIG. 5 and comprises the following components in the sequence described below:
optionally a substrate (1),
a gate electrode (2),
an organic dielectric layer as gate insulator (3),
source and drain (S/D) electrodes (4),
an organic semiconductor layer (5),
optionally a protection layer (not shown) on top of the semiconductor layer (5) and the source and drain electrodes (4).

The process for preparing this device comprises the steps of applying a gate electrode (2) on a substrate (1), applying a dielectric layer (3) on top of the gate electrode (2) and the substrate (1), applying a layer of a conducting material, preferably a metal or conducting oxide, on top of the dielectric layer (3) by a CFUBMSIP process, optionally followed by structuring the layer of conducting material, for example using standard photolithography techniques, to form the S/D electrodes (4), and applying a semiconductor layer (5) on top of or between the S/D electrodes (4).

The other components or functional layers of the electronic devices, like the substrate, the gate electrode, the dielectric layer, and the organic semiconductor, can be selected from standard materials and can be manufactured and applied to the device by standard methods. Suitable materials and manufacturing methods for these components and layers are known to the skilled person and are described in the literature, for example in US 2007/0102696 A1 or U.S. Pat. No. 7,095,044.

The application methods include liquid coating and vapour or vacuum deposition. Preferred deposition techniques include, without limitation, dip coating, spin coating, ink jet printing, letter-press printing, screen printing, doctor blade coating, roller printing, reverse-roller printing, offset lithography printing, flexographic printing, web printing, spray coating, brush coating or pad printing. Ink-jet printing is particularly preferred as it allows high resolution layers and devices to be prepared.

Generally the thickness of a functional layer in an electronic device according to the present invention may be from 1 nm (in case of a monolayer) to 10 μm, preferably from 1 nm to 1 μm, more preferably from 1 nm to 500 nm.

Various substrates may be used for the fabrication of organic electronic devices, for example glass or plastics, plastics materials being preferred, examples including alkyd resins, allyl esters, benzocyclobutenes, butadiene-styrene, cellulose, cellulose acetate, epoxide, epoxy polymers, ethylene-chlorotrifluoro ethylene, ethylene-tetra-fluoroethylene, fibre glass enhanced plastic, fluorocarbon polymers, hexafluoropropylenevinylidene-fluoride copolymer, high density polyethylene, parylene, polyamide, polyimide, polyaramid, polydimethylsiloxane, polyethersulphone, polyethylene, polyethylenenaphthalate, polyethyleneterephthalate, polyketone, polymethylmethacrylate, polypropylene, polystyrene, polysulphone, polytetrafluoroethylene, polyurethanes, polyvinylchloride, silicone rubbers, silicones. Preferred substrate materials are polyethyleneterephthalate, polyimide, and polyethylenenaphthalate. The substrate may be any plastic material, metal or glass coated with the above materials. The substrate should preferably be homogenous to ensure good pattern definition. The substrate may also be uniformly pre-aligned by extruding, stretching, rubbing or by photochemical techniques to induce the orientation of the organic semiconductor in order to enhance carrier mobility.

The dielectric material for the insulator layer is an organic material. It is preferred that the dielectric layer is solution coated which allows ambient processing, but could be also deposited by various vacuum deposition techniques. When the dielectric is being patterned, it may perform the function of interlayer insulation or act as gate insulator for an OFET. Preferred deposition techniques include, without limitation, dip coating, spin coating, ink jet printing, letter-press printing, screen printing, doctor blade coating, roller printing, reverse-roller printing, offset lithography printing, flexographic printing, web printing, spray coating, brush coating or pad printing. Ink-jet printing is particularly preferred as it allows high resolution layers and devices to be prepared. Optionally, the dielectric material could be cross-linked or cured to achieve better resistivity against solvents and/or structural integrity and/or to enable patternability (photolithography) Preferred gate insulators are those that provide a low permittivity interface to the organic semiconductor.

As semiconductor material for example amorphous or polycrystalline silicon, or organic semiconductor (OSC) materials can be used. Suitable materials and methods for providing the semiconductor layer are known to the skilled person and described in the literature.

In case of OFET devices, where the OFET layer is an OSC, an n-type or p-type OSC may be used, which can be deposited by vacuum or vapour deposition, or preferably deposited from a solution. Preferred OSCs have a FET mobility of greater than 10⁻⁵ cm²V⁻¹s⁻¹.

The OSC is used for example as the active channel material in an OFET or a layer element of an organic rectifying diode. OSCs that are deposited by liquid coating to allow ambient processing are preferred. OSCs are preferably spray-, dip-, web- or spin-coated or deposited by any liquid coating technique. Ink-jet deposition is also suitable. The OSC may optionally be vacuum or vapour deposited.

The semiconducting channel may also be a composite of two or more of the same types of semiconductors. Furthermore, a p-type channel material may, for example be mixed with n-type materials for the effect of doping the layer. Multilayer semiconductor layers may also be used. For example the semiconductor may be intrinsic near the insulator interface and a highly doped region can additionally be coated next to the intrinsic layer.

The OSC material may be any conjugated aromatic molecule containing at least three aromatic rings. The OSCs preferably contain 5, 6 or 7 membered aromatic rings, and more preferably contain 5 or 6 membered aromatic rings. The material may be a monomer, oligomer or polymer, including mixtures, dispersions and blends.

Each of the aromatic rings optionally contains one or more hetero atoms selected from Se, Te, P, Si, B, As, N, O or S, preferably from N, O or S.

The aromatic rings may be optionally substituted with alkyl, alkoxy, polyalkoxy, thioalkyl, acyl, aryl or substituted aryl groups, halogen, particularly fluorine, cyano, nitro or an optionally substituted secondary or tertiary alkylamine or arylamine represented by —N(R³)(R⁴), where R³ and R⁴ each independently is H, optionally substituted alkyl, optionally substituted aryl, alkoxy or polyalkoxy groups. Where R³ and R⁴ is alkyl or aryl these may be optionally fluorinated.

The rings may be optionally fused or may be linked with a conjugated linking group such as —C(T₁)=C(T₂)-, —C≡C—, —N(R′)—, —N═N—, (R′)═N—, —N═C(R′)—. T₁ and T₂ each independently represent H, Cl, F, —C≡N or lower alkyl groups particularly C₁₋₄ alkyl groups; R′ represents H, optionally substituted alkyl or optionally substituted aryl. Where R′ is alkyl or aryl these may be optionally fluorinated.

Other OSC materials that can be used in this invention include compounds, oligomers and derivatives of compounds of the following: conjugated hydrocarbon polymers such as polyacene, polyphenylene, poly(phenylene vinylene), polyfluorene including oligomers of those conjugated hydrocarbon polymers; condensed aromatic hydrocarbons such as tetracene, chrysene, pentacene, pyrene, perylene, coronene, or substituted derivatives of these; oligomeric para substituted phenylenes such as p-quaterphenyl (p-4P), p-quinquephenyl (p-5P), p-sexiphenyl (p-6P), or soluble substituted derivatives of these; conjugated heterocyclic polymers such as poly(3-substituted thiophene), poly(3,4-bisubstituted thiophene), polybenzothiophene, polyisothianapthene, poly(N-substituted pyrrole), poly(3-substituted pyrrole), poly(3,4-bisubstituted pyrrole), polyfuran, polypyridine, poly-1,3,4-oxadiazoles, polyisothianaphthene, poly(N-substituted aniline), poly(2-substituted aniline), poly(3-substituted aniline), poly(2,3-bisubstituted aniline), polyazulene, polypyrene; pyrazoline compounds; polyselenophene; polybenzofuran; polyindole; polypyridazine; benzidine compounds; stilbene compounds; triazines; substituted metallo- or metal-free porphines, phthalocyanines, fluorophthalocyanines, naphthalocyanines or fluoronaphthalocyanines; C₆₀ and C₇₀ fullerenes; N,N′-dialkyl, substituted dialkyl, diaryl or substituted diaryl-1,4,5,8-naphthalenetetracarboxylic diimide and fluoro derivatives; N,N′-dialkyl, substituted dialkyl, diaryl or substituted diaryl 3,4,9,10-perylenetetracarboxylicdiimide; bathophenanthroline; diphenoquinones; 1,3,4-oxadiazoles; 11,11,12,12-tetracyanonaptho-2,6-quinodimethane; α,α′-bis(dithieno[3,2-b2′,3′-d]thiophene); 2,8-dialkyl, substituted dialkyl, diaryl or substituted diaryl anthradithiophene; 2,2′-bibenzo[1,2-b:4,5-b′]dithiophene. Preferred compounds are those from the above list and derivatives thereof which are soluble.

Especially preferred OSC materials are substituted heteroacenes or pentacenes, in particular 6,13-bis(trialkylsilylethynyl)pentacene, or heteroacene derivatives or substituted derivatives thereof, as described in U.S. Pat. No. 6,690,029 or US 2007/0102696 A1.

Optionally, the OSC layer comprises one or more organic binders, to adjust the rheological properties, as described for example in US 2007/0102696 A1.

Unless the context clearly indicates otherwise, as used herein plural forms of the terms herein are to be construed as including the singular form and vice versa.

Throughout the description and claims of this specification, the words “comprise” and “contain” and variations of the words, for example “comprising” and “comprises”, mean “including but not limited to”, and are not intended to (and do not) exclude other components.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

It will be appreciated that many of the features described above, particularly of the preferred embodiments, are inventive in their own right and not just as part of an embodiment of the present invention. Independent protection may be sought for these features in addition to or alternative to any invention presently claimed.

The invention will now be described in more detail by reference to the following examples, which are illustrative only and do not limit the scope of the invention.

### COMPARATIVE EXAMPLE 1

### Deposition of Source/Drain (S/D) Electrodes in a Bottom Gate (BG) Field Effect Transistor (FET) Using a Standard Thermal Evaporation Techniques

In order to establish a benchmark performance of the materials employed here, a BG FET is prepared as follows:

A glass substrate, Eagle Glass 1737®, is sonicated in a 3% solution of Decon90® at 65° C. for 30 minutes. The glass substrate is washed with fresh distilled water, followed by sonication in distilled water for a further 1 minute at 65° C. Finally, the substrate is sonicated in methanol for 1 minute at RT followed by rinsing with fresh methanol and spin dried using a spin coater set at 2000 rpm for 30 seconds.

A 30 nm aluminum gate electrode is applied to the glass substrate via a shadow mask. The aluminum is deposited using an Edwards® Auto 306 Thermal Evaporator System. The aluminum gate is treated with the adhesion promoter Lisicon™ M009, followed by deposition of an approximately 900 nm thick layer of the Organic Gate Insulator (OGI) Lisicon™ D181 or D203 (all available from Merck KgaA, Darmstadt, Germany) using a spin coater.

A 30 nm thick silver layer is applied to the OGI via a shadow mask to form the source/drain electrodes. This is deposited using an Edwards® Auto 306 Turbo Thermal Evaporator System.

The silver source/drain electrodes are covered with a SAM material for 90 seconds and then spun at 1500 rpm for 20 seconds to remove the excess. The substrate is then rinsed with fresh Isopropanol and spun for a further 20 seconds at 1500 rpm till dry.

Finally an OSC layer of Lisicon™ S1340 (from Merck KGaA) is deposited by spin coating.

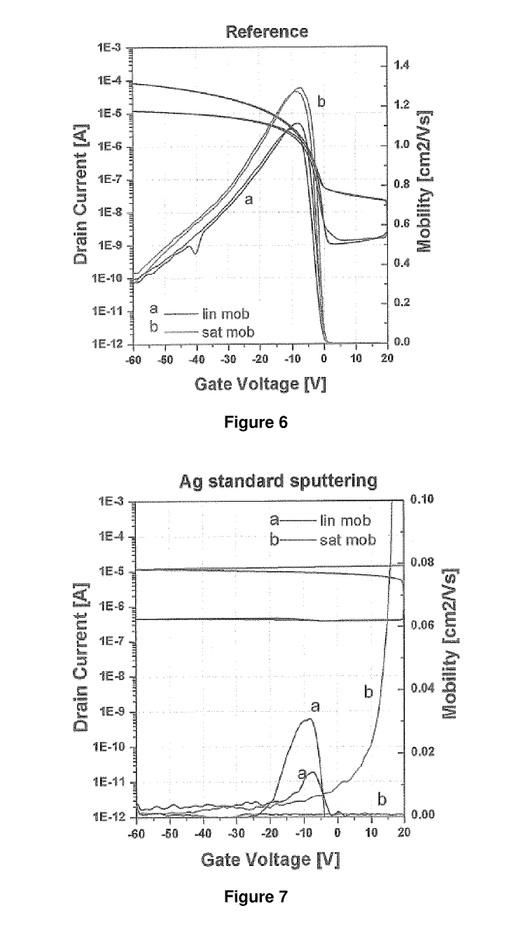

In the method described above, the Ag electrode is deposited onto the gate dielectric by thermal evaporation through a shadow mask. In this case there is no damage to the organic dielectric, as can be seen from FIG. 6, which shows the transistor characteristic of the BG FET device (with the dielectric Lisicon™ D203).

This device is used as a reference device for the following examples.

### COMPARATIVE EXAMPLE 2

### Deposition of S/D Electrodes in a BG FET Using a Standard Sputtering Technique

It is not possible to sputter through a shadow mask with the resolution required for a transistor with a channel length in the region of several microns. To overcome this issue, in this example a full metal layer is deposited on top of the organic material and then structured using standard photolithography techniques to form the S/D electrodes.

A glass substrate, Eagle Glass 1737®, is sonicated in a 3% solution of Decon90® at 65° C. for 30 minutes. The glass substrate is washed with fresh distilled water, followed by sonication in distilled water for a further 1 minute at 65° C. Finally, the substrate is sonicated in methanol for 1 minute at RT followed by rinsing with fresh methanol and spin dried using a spin coater set at 2000 rpm for 30 seconds.

A 30 nm aluminum gate electrode is applied to the glass substrate via a shadow mask. The aluminum is deposited using an Edwards® Auto 306 Thermal Evaporator System. The aluminum gate is treated with the adhesion promoter Lisicon™ M009, followed by deposition of an approximately 900 nm thick layer of the Organic Gate Insulator (OGI) Lisicon™ D181 or D203 (all available from Merck KgaA, Darmstadt, Germany) using a spin coater.

A 30 nm thick silver layer is deposited on to the OGI using standard (magnetron) sputtering techniques with normal powers in the range of 100 W to 500 W.

This layer is then structured to form source/drain electrodes using standard photolithographic techniques.

The silver source/drain electrodes are covered with a SAM material for 90 seconds and then spun at 1500 rpm for 20 seconds to remove the excess. The substrate is then rinsed with fresh Isopropanol and spun for a further 20 seconds at 1500 rpm till dry.

Finally an OSC layer of Lisicon™ S1340 (from Merck KGaA) is deposited by spin coating.

FIG. 7 shows the transistor characteristic of the FET thereby obtained (with the dielectric Lisicon™ D203). It can be seen that standard magnetron sputtering has a detrimental effect of performance, and that the device does not behave as a transistor anymore. The drain current is completely independent of the gate voltage, i.e., the transistor does not switch off.

In order to elucidate if the damage is due to the exposure to plasma during the sputtering process itself or to the influence of the chemicals employed during the photolithography process, an additional transistor is prepared. This transistor is built as described in Comparative Example 1 with the exception that the dielectric layer is exposed to the etchant by means of immersion of the sample in it for at least the time required to etch the silver layer in the example above.

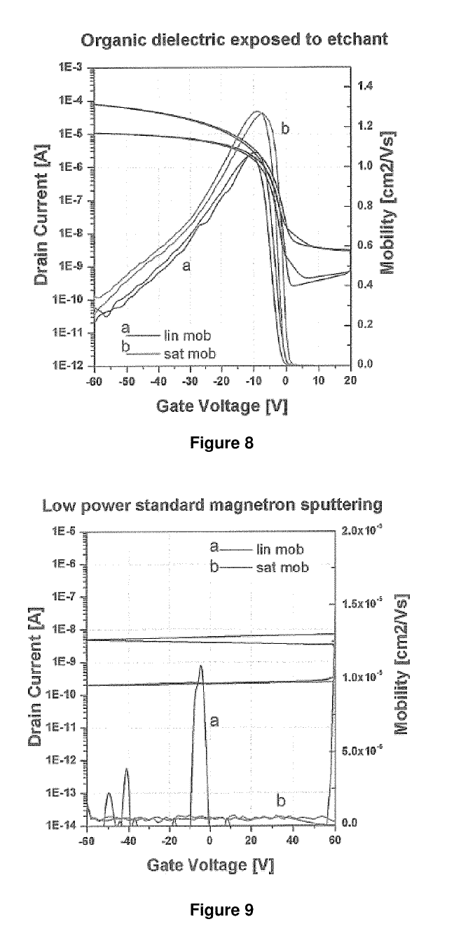

FIG. 8 shows the transistor characteristic, transfer curve, corresponding to the transistor which is nearly identical to the one as shown in FIG. 6. The direct conclusion is that the dielectric is not affected by the etchant and the only damage is caused (or induced) by the sputtering process.

### COMPARATIVE EXAMPLE 3

### Deposition of S/D Electrodes in a BG FET Using Sputtering with Low Power to Minimise the Plasma Effect

One way of reducing the damage to the organic dielectric could be to use a lower energy process for the sputtering of the metal. This would be a convenient way of sputtering still using standard equipment. To test that possibility a transistor is prepared using the following procedure.

A glass substrate, Eagle Glass 1737®, is sonicated in a 3% solution of Decon90® at 65° C. for 30 minutes. The glass substrate is washed with fresh distilled water, followed by sonication in distilled water for a further 1 minute at 65° C. Finally, the substrate is sonicated in methanol for 1 minute at RT followed by rinsing with fresh methanol and spin dried using a spin coater set at 2000 rpm for 30 seconds.

A 30 nm aluminum gate electrode is applied to the glass substrate via a shadow mask. The aluminum is deposited using an Edwards® Auto 306 Thermal Evaporator System. The aluminum gate is treated with the adhesion promoter Lisicon™ M009, followed by deposition of an approximately 900 nm thick layer of the Organic Gate Insulator (OGI) Lisicon™ D181 or D203 (all available from Merck KgaA, Darmstadt, Germany) using a spin coater.

A 30 nm thick silver layer is deposited on to the OGI using standard (magnetron) sputtering techniques with normal sputtering powers in the range of 5 W to 50 W.

This layer is then structured to form source/drain electrodes using standard photolithographic techniques.

The silver source/drain electrodes are covered with a SAM material for 90 seconds and then spun at 1500 rpm for 20 seconds to remove the excess. The substrate is then rinsed with fresh Isopropanol and spun for a further 20 seconds at 1500 rpm till dry.

Finally an OSC layer of Lisicon™ S1340 (from Merck KGaA) is deposited by spin coating.

FIG. 9 shows the transistor characteristic of the FET thereby obtained (with the dielectric Lisicon™ D203). It can be seen that the device does not have the desired performance. This shows that even by reducing the plasma power in the MSIP process the device does not perform as a transistor.

### EXAMPLE 1

### BG FET with Sputtered Silver S/D Electrodes Using CFUBMSIP

By using the CFUBMSIP sputtering technique it can be shown that, due to the confinement of the plasma far away from the samples, the surface of the organic dielectric is not damaged. To prove the benefit of this technique a transistor is prepared as follows:

A glass substrate, Eagle Glass 1737®, is sonicated in a 3% solution of Decon90® at 65° C. for 30 minutes. The glass substrate is washed with fresh distilled water, followed by sonication in distilled water for a further 1 minute at 65° C. Finally, the substrate is sonicated in methanol for 1 minute at RT followed by rinsing with fresh methanol and spin dried using a spin coater set at 2000 rpm for 30 seconds.

A 30 nm aluminum gate electrode is applied to the glass substrate via a shadow mask. The aluminum is deposited using an Edwards® Auto 306 Thermal Evaporator System. The aluminum gate is treated with the adhesion promoter Lisicon™ M009, followed by deposition of an approximately 900 nm thick layer of the Organic Gate Insulator (OGI) Lisicon™ D181 or D203 (all available from Merck KgaA, Darmstadt, Germany) using a spin coater.

A 30 nm thick silver layer is deposited on to the OGI using CFUBMSIP sputtering technique with normal powers in the range of 100 W to 500 W.

This layer is then structured to form source/drain electrodes using standard photolithographic techniques.

The silver source/drain electrodes are covered with a SAM material for 90 seconds and then spun at 1500 rpm for 20 seconds to remove the excess. The substrate is then rinsed with fresh Isopropanol and spun for a further 20 seconds at 1500 rpm till dry.

Finally an OSC layer of Lisicon™ S1340 (from Merck KGaA) is deposited by spin coating.

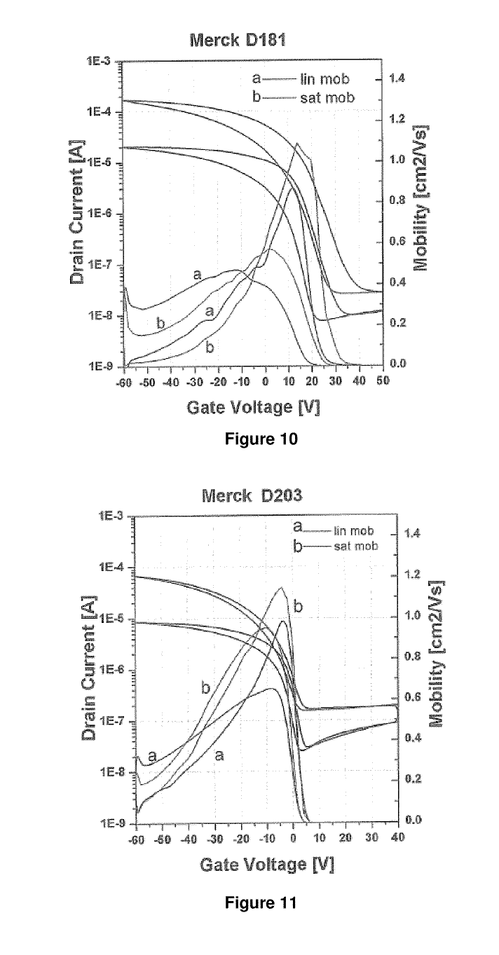

FIGS. 10 and 11 show the transistor characteristics of the FETs thereby obtained (with the OGI D181 and D203, respectively). This clearly illustrates that the surface of the organic dielectric, and the interface between the organic dielectric and the OSC layer, are not significantly damaged. It is also important to note that in this case two different dielectrics are used, showing that the versatility of process to be used with different materials.

This also shows that the CFUBMSIP process provides advantages compared to a conventional MSIP process even with reduced plasma power as used in Comparative Example 3.

### EXAMPLE 2

### BG FET with Sputtered ITO S/D Electrodes Using CFUBMSIP

A glass substrate, Eagle Glass 1737®, is sonicated in a 3% solution of Decon90® at 65° C. for 30 minutes. The glass substrate is washed with fresh distilled water, followed by sonication in distilled water for a further 1 minute at 65° C. Finally, the substrate is sonicated in methanol for 1 minute at RT followed by rinsing with fresh methanol and spin dried using a spin coater set at 2000 rpm for 30 seconds.

A 30 nm aluminum gate electrode is applied to the glass substrate via a shadow mask. The aluminum is deposited using an Edwards® Auto 306 Thermal Evaporator System. The aluminum gate is treated with the adhesion promoter Lisicon™ M009, followed by deposition of an approximately 900 nm thick layer of the Organic Gate Insulator (OGI) Lisicon™ D181 or D203 (all available from Merck KgaA, Darmstadt, Germany) using a spin coater.

A 30 nm thick ITO is deposited on to the OGI using CFUBMSIP sputtering techniques with normal powers in the range of 100 W to 500 W. This layer is then structured to form source/drain using standard photolithographic techniques.

The source/drain electrodes are covered with a SAM material for 90 seconds and then spun at 1500 rpm for 20 seconds to remove the excess. The substrate is then rinsed with fresh Isopropanol and spun for a further 20 seconds at 1500 rpm till dry.

Finally an OSC layer of Lisicon™ S1340 (from Merck KGaA) is deposited by spin coating.

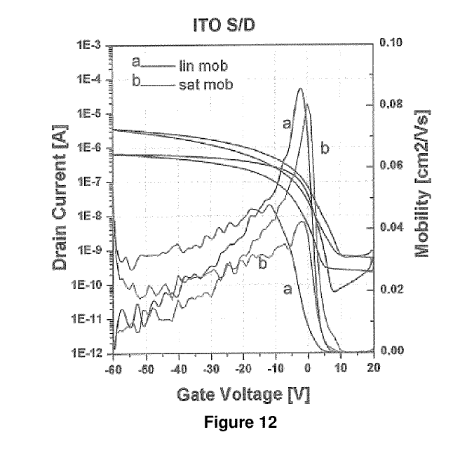

FIG. 12 shows the characteristic transfer curve and mobilities for the FET fabricated using this method (with the dielectric Lisicon™ D203).

The observed mobilities are lower than the benchmark shown in Comparative Example 1. However, this can be attributed to the lower conductivity of ITO with respect to Ag since the process was not optimised for ITO fabrication. It is also possible that there is a workfunction mismatch between the ITO workfunction and the OSC ionization potential.

1. Process of depositing a conducting material onto an organic material by closed field unbalanced magnetron sputter ion plating.

2. Process of manufacturing an optical, electrooptical or organic electronic device or a component thereof, including the step of depositing a layer of a conducting material onto a layer of an organic material by closed field unbalanced magnetron sputter ion plating.

3. Process according to claim 1, characterized in that it uses a magnetron sputter ion plating system comprising
holding means for supporting a substrate to be coated,
electric field means generating an electric field directed towards said substrate to be coated,
magnetic field means comprising at least two magnetrons, each having an inner pole and an outer pole, said outer pole being of polarity opposite to that of said inner pole,
wherein in use a substrate to be coated is provided at said holding means and is electrically biased by said electric field to be a cathode so as to attract ions to the substrate,
and wherein at least one of said magnetrons is an unbalanced magnetron, and said outer pole of one said magnetron and said outer ring pole of another adjacent magnetron are of opposite polarity and are near enough to each other so that a substantial magnetic field extends between said outer poles, so as to prevent substantial escape of ionizing electrons between the adjacent magnetrons so that these said electrons are not lost and are available to increase the ionization at said electrically biased substrate,
and wherein said magnetic field means generates a plasma holding field, said plasma holding field being generated by direct magnetic linkage between said outer poles of said adjacent magnetrons, and wherein said substrate is inside said plasma holding field.

4. Process according to claim 1, characterized in that the organic material is a dielectric material.

5. Process according to claim 2, characterized in that the layer of organic material is a gate insulator layer.

6. Process according to claim 1, characterized in that the organic material is an organic polymer or a crosslinked organic polymer.

7. Process according to claim 1, characterized in that the organic material is selected from the group consisting of fluorinated or perfluorinated hydrocarbon polymers, BCB (benzocyclobutene) or BCB polymers, polyacrylates, polycycloolefins, fluorinated para-xylene, fluoropolyarylether, fluorinated polyimide, polystyrene, poly(α-methylstyrene), poly(α-vinylnaphthalene), poly(vinyltoluene), polyethylene, cis-polybutadiene, polypropylene, polyisoprene, poly(4-methyl-1-pentene), poly(4-methylstyrene), poly(chlorotrifluoroethylene), poly(2-methyl-1,3-butadiene), poly(p-xylylene), poly(α-α-α′-α′tetrafluoro-p-xylylene), poly[1,1-(2-methyl propane)bis(4-phenyl)carbonate], poly(cyclohexyl methacrylate), poly(chlorostyrene), poly(2,6-dimethyl-1,4-phenylene ether), polyisobutylene, poly(vinyl cyclohexane), poly(vinylcinnamate), poly(4-vinylbiphenyl), poly(1,3-butadiene), polyphenylene, polycycloolefins, regular, random or block copolymers of poly(ethylene/tetrafluoroethylene), poly(ethylene/chlorotrifluoro-ethylene), fluorinated ethylene/propylene copolymer, polystyrene-co-α-methylstyrene, ethylene/ethyl acrylate copolymer, poly(styrene/10% butadiene), poly(styrene/15% butadiene), poly(styrene/2,4 dimethylstyrene), and copolymers containing one or more monomer units of the aforementioned polymers.

8. Process according to claim 1, characterized in that the organic material is selected from the group consisting of polypropylene, polyisobutylene, poly(4-methyl-1-pentene), polyisoprene, poly(vinyl cyclohexane), BCB polymers, polyacrylates, polycycloolefins, fluorinated hydrocarbon copolymers, perfluorinated hydrocarbon polymers, and copolymers containing one or more monomer units of the aforementioned polymers.

9. Process according to claim 8, characterized in that the organic material is selected from BCB polymers, polycycloolefins and polyacrylates.

10. Process according to claim 1, characterized in that the organic material has a permittivity from 1.0 to 5.0.

11. Process according to claim 10, characterized in that the organic material has a permittivity from 1.8 to 4.0.

12. Process according to claim 2, characterized in that the layer of conducting material is an electrode.

13. Process according to claim 1, characterized in that the conducting material is selected from the group consisting of metals, metal oxides, metal sulphides, metal nitrides, carbon, silicon oxide, silicon nitride, or mixtures or combinations of one or more of the aforementioned.

14. Process according to claim 13, characterized in that the conducting material is selected from the group consisting of Au, Ag, Cu, Al, Ni, Co, Cu, Cr, Pt, Pd, Ca, W, In, Pb, ITO (indium tin oxide), AZO (aluminum zinc oxides) and GaInZnO.

15. Process according to claim 1, characterized in that the layer of the sputtered conducting material has a thickness from 5 nm to 1 μm.

16. Process according to claim 1, characterized in that it comprises the steps of applying a gate electrode (2) on a substrate (1), applying a dielectric layer (3) on top of the gate electrode (2) and the substrate (1), applying a layer of a conducting material on top of the dielectric layer (3) by a closed field unbalanced magnetron sputter ion plating process, and optionally structuring the layer of conducting material, to form source and drain electrodes (4), and applying a semiconductor layer (5) on top of or between the source and drain electrodes (4).

17. Optical, electrooptical or organic electronic device, or a component thereof, obtainable or obtained by a process according to claim 1.

18. Device or component according to claim 17, characterized in that it is selected from the group consisting of electrooptical displays, liquid crystal displays (LCDs), optical information storage devices, electronic devices, organic semiconductors, organic field effect transistors (OFET), integrated circuits (IC), organic thin film transistors (OTFT), Radio Frequency Identification (RFID) tags, organic light emitting diodes (OLED), organic light emitting transistors (OLET), electroluminescent displays, organic photovoltaic (OPV) devices, organic solar cells (O-SC), organic laser diodes (O-laser), organic integrated circuits (O-IC), lighting devices, flat panel displays (FPD), sensor devices, electrode materials, photoconductors, photodetectors, electrophotographic recording devices, capacitors, charge injection layers, Schottky diodes, planarising layers, antistatic films, conducting substrates, conducting patterns.

19. Device or component according to claim 18, characterized in that it is a bottom gate organic thin film or organic field effect transistor.

20. Device according to claim 19, characterized in that it comprises the following components in the sequence described below:
optionally a substrate (1),
a gate electrode (2),
an organic dielectric layer as gate insulator (3),
source and drain electrodes (4),
an organic semiconductor layer (5),
optionally a protection layer on top of the semiconductor layer (5) and the source and drain electrodes (4).
